(19) United States
(12) Patent Application Publication
(10) Pub. No.: US 2014/0159158 A1
(43) Pub. Date: Jun. 12, 2014

(54) Semiconductor Devices

(71) Applicants: Ho-Jun Kim, Suwon-si (KR); Chulhong Park, Seongnam-si (KR); Jung-Ho Do, Yongin-si (KR); Sang-Pil Sim, Seongnam-si (KR); Jongshik Yoon, Yongin-si (KR); Kwanyoung Chun, Suwon-si (KR)

(72) Inventors: Ho-Jun Kim, Suwon-si (KR); Chulhong Park, Seongnam-si (KR); Jung-Ho Do, Yongin-si (KR); Sang-Pil Sim, Seongnam-si (KR); Jongshik Yoon, Yongin-si (KR); Kwanyoung Chun, Suwon-si (KR)

(21) Appl. No.: 14/100,054

(22) Filed: Dec. 9, 2013

(30) Foreign Application Priority Data
Dec. 10, 2012 (KR) 10-2012-0142902

(51) Int. Cl. H01L 27/088

(52) U.S. Cl. CPC H01L 27/088
USPC 257/368

(57) ABSTRACT

A semiconductor device includes transistors provided on a substrate and including first dopant regions, first contacts extending from the first dopant regions in a first direction, a long via provided on the first contacts and connected in common to first contacts that are adjacent one another, and a common conductive line provided on the long via and extending in a second direction crossing the first direction. The common conductive line electrically connects the first dopant regions to each other.

### CROSS-REFERENCE TO RELATED APPLICATIONS

This U.S. non-provisional patent application claims priority under 35 U.S.C. §119 to Korean Patent Application No. 10-2012-0142902, filed on Dec. 10, 2012, the entirety of which is incorporated by reference herein.

### BACKGROUND

The inventive concepts relate to semiconductor devices and, more particularly, to semiconductor devices including a plurality of transistors.

Semiconductor devices are very attractive in the electronic industry because of their small size, multi-function, and/or low manufacture costs. Semiconductor devices may be categorized as any one of semiconductor memory devices storing logic data, semiconductor logic devices processing operations of logic data, and hybrid semiconductor devices having both the function of the semiconductor memory devices and the function of the semiconductor logic devices. Semiconductor devices having excellent characteristics have been increasingly demanded with the development of the electronic industry. For example, high reliability, high speed, and/or multi-functional semiconductor devices have been increasingly demanded. To satisfy the demands, the complexity of structures in semiconductor devices has increased, and the semiconductor devices have become more highly integrated.

### SUMMARY

Embodiments of the inventive concept may provide semiconductor devices including a via electrically connecting a plurality of contacts to a conductive line without employment of a plurality of masks.

In one aspect, a semiconductor device may include: a plurality of transistors provided on a substrate, the plurality of transistors including first dopant regions; first contacts extending from the first dopant regions in a first direction; a long via provided on the first contacts, the long via connected in common to a plurality of first contacts adjacent to each other of the first contacts; and a common conductive line provided on the long via and extending in a second direction crossing the first direction, the common conductive line electrically connecting the first dopant regions to each other.

In an embodiment, the semiconductor device may further include: a device isolation layer disposed in the substrate. The common conductive line may vertically overlap with the device isolation layer and may extend along the device isolation layer.

In an embodiment, the device isolation layer may include: a first device isolation layer provided under the common conductive line and extending along the common conductive line; and a second device isolation layer defining an active region of the substrate. The first device isolation layer may be thicker than the second device isolation layer.

In an embodiment, the plurality of transistors may be disposed at both sides of the first device isolation layer; and the first contacts may extend onto the first device isolation layer.

In an embodiment, ends of the first contacts of the transistors disposed at a side of the first device isolation layer may be aligned with each other in an extending direction of the common conductive line.

In an embodiment, the long via may include the same material as the common conductive line; and an interface may not exist between the long via and the common conductive line.

In an embodiment, a top surface of the long via may be in contact with a bottom surface of the common conductive line.

In an embodiment, a top surface of the long via may be completely covered by the common conductive line.

In an embodiment, a width of the long via in the first direction may be less than a width of the common conductive line in the first direction.

In an embodiment, the width of the long via in the first direction may be less than a width of the long via in the second direction.

In an embodiment, a thickness of the long via may be about 2 times to about 4 times greater than a thickness of the first contact.

In an embodiment, the long via may include a plurality of long vias; and the plurality of long vias may be spaced apart from each other in the second direction.

In an embodiment, a distance between the plurality of long vias may be equal to or greater than twice a minimum pitch between gates of the plurality of transistors.

In an embodiment, a distance between the plurality of long vias may be greater than a distance between the first contacts connected to one of the long vias.

In an embodiment, some of the first contacts connected to the long via may be physically connected to each other.

In an embodiment, at least one of the first contacts may include: a first portion; and a second portion extending from the first portion under the long via. A width of the second portion may be greater than a width of the first portion.

In an embodiment, the plurality of transistors may further include second dopant regions. In this case, the semiconductor device may further include: second contacts disposed on the second dopant regions; and third contacts disposed on gate electrodes of the plurality of transistors.

In an embodiment, the semiconductor device may further include: second vias disposed on the second contacts; and third vias disposed on the third contacts. The second vias and the third vias may be disposed at substantially the same level as the long via from a top surface of the substrate.

In an embodiment, a distance between the long via and the second via or third via may be equal to or greater than a minimum pitch between the gate electrodes.

In an embodiment, the semiconductor device may further include: a second conductive line disposed on the second via; and a third conductive line disposed on the third via. The second and third conductive lines may be disposed at substantially the same level as the common conductive line from the top surface of the substrate.

In an embodiment, the plurality of transistors may be the same conductive type of transistors.

In an embodiment, the plurality of transistors may be NMOS transistors; and the first dopant regions may be source regions of the plurality of transistors.

In an embodiment, the plurality of transistors may be PMOS transistors; and the first dopant regions may be drain regions of the plurality of transistors.

In another aspect, a semiconductor device may include: a device isolation layer disposed in a substrate and extending in one direction; a plurality of transistors disposed at both sides of the device isolation layer, the plurality of transistors including first dopant regions; first contacts extending from the first dopant regions onto the device isolation layer; a long via provided on the first contacts, the long via connected in common to a plurality of first contacts adjacent to each other of the first contacts; and a common conductive line connected to a top surface of the long via, the common conductive line extending along the device isolation layer.

In an embodiment, the first contacts may extend in a direction crossing an extending direction of the common conductive line.

In an embodiment, the common conductive line may be electrically connected to the first dopant regions.

In an embodiment, the top surface of the long via may be in contact with a bottom surface of the common conductive line; and the top surface of the long via may be completely covered by the common conductive line.

In an embodiment, a width of the long via may be less than a width of the common conductive line in a direction crossing an extending direction of the common conductive line.

In an embodiment, the long via may include a plurality of long vias; and the plurality of long vias may be spaced apart from each other in an extending direction of the common conductive line.

In an embodiment, a distance between the plurality of long vias may be equal to or greater than twice a minimum pitch between gates of the plurality of transistors.

In an embodiment, a distance between the plurality of long vias may be greater than a distance between the first contacts connected to one of the long vias.

In an embodiment, some of the first contacts connected to the long via may be physically connected to each other.

In still another aspect, a semiconductor device may include: a plurality of transistors provided on a substrate and including first dopant regions; contacts extending from the first dopant regions in one direction; and a common conductive line provided on the contacts and extending in a direction crossing the one direction, the common conductive line electrically connected to the first dopant regions. The common conductive line may include a long via protruding from a bottom surface of the common conductive line toward the substrate; and the long via of the common conductive line may be connected in common to a plurality of first contacts adjacent to each other of the first contacts.

### BRIEF DESCRIPTION OF THE DRAWINGS

The inventive concepts will become more apparent in view of the attached drawings and accompanying detailed description.

FIG. 1 is a plan view illustrating a semiconductor device according to some embodiments of the inventive concept.

FIG. 2 is an enlarged view of a NMOS transistor region or a PMOS transistor region of FIG. 1.

FIG. 3 is an enlarged view of FIG. 2.

FIG. 4A is a cross-sectional view taken along a line A-A′ of FIG. 3.

FIG. 4B is a cross-sectional view taken along a line B-B′ of FIG. 3.

FIGS. 5 and 6 are plan views illustrating transistor regions according to other embodiments of the inventive concept.

FIGS. 7 to 10 are plan views illustrating arrangement and shapes of first contacts in more detail.

FIGS. 11 and 12 are plan views illustrating other examples of a structure of a first contact according to example embodiments of the inventive concept.

FIGS. 13A, 13B, 14A, and 14B are cross-sectional views illustrating methods of fabricating a semiconductor device according to some embodiments of the inventive concept.

FIGS. 15A and 15B are cross-sectional views illustrating a method of fabricating a semiconductor device according to other embodiments of the inventive concept.

FIG. 16 illustrates another example of an active region of a semiconductor device according to example embodiments of the inventive concept.

FIG. 17 illustrates still another example of an active region of a semiconductor device according to example embodiments of the inventive concept.

FIG. 18 is a schematic block diagram illustrating an example of electronic systems including semiconductor devices according to embodiments of the inventive concept.

### DETAILED DESCRIPTION OF THE EMBODIMENTS

The inventive concepts will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

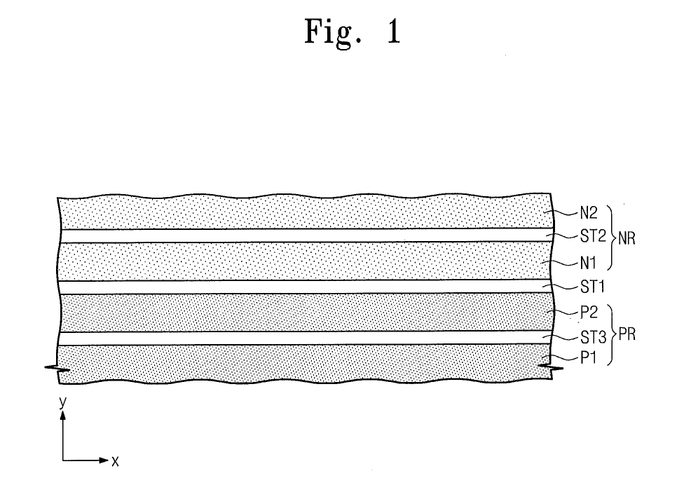

FIG. 1 is a plan view illustrating a semiconductor device according to some embodiments of the inventive concept. A semiconductor device will be described with reference to FIG. 1. The semiconductor device may include logic cells disposed on an NMOS transistor region NR and a PMOS transistor region PR. Hereinafter, the logic cell may be defined in the present specification as a unit for performing one logic operation. The NMOS transistor region NR and the PMOS transistor region PR may be separated from each other by a device isolation layer ST1. The NMOS transistor region NR may include a first NMOS region N1 and a second NMOS region N2 that are separated from each other by a device isolation layer ST2. The PMOS transistor region PR may include a first PMOS region P1 and a second PMOS region P2 that are separated from each other by a device isolation layer ST3. In some embodiments, the NMOS transistor region NR and the PMOS transistor region PR may be alternately and repeatedly arranged.

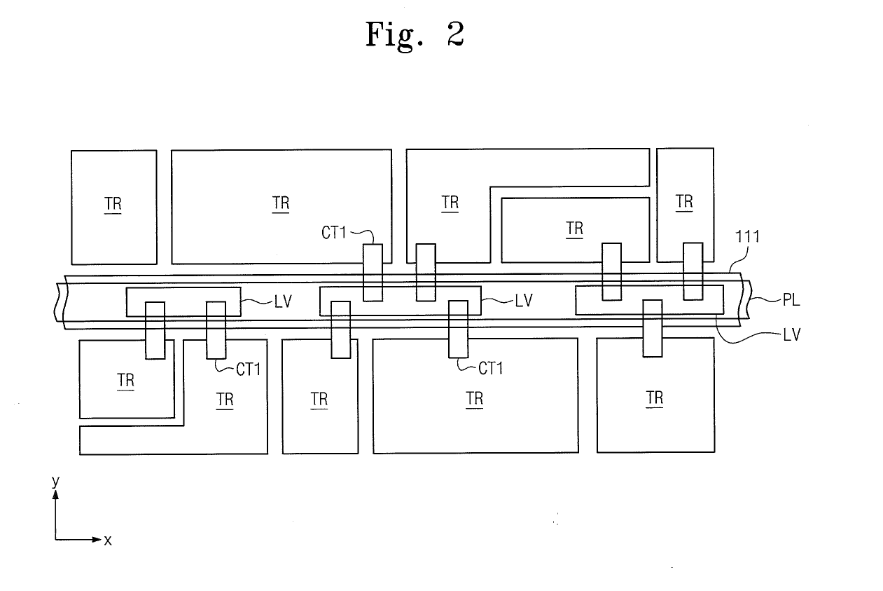

FIG. 2 is an enlarged view of a NMOS transistor region NR or a PMOS transistor region PR of FIG. 1. In other words, the region (hereinafter, referred to as ‘a semiconductor region’) illustrated in FIG. 2 may correspond to the NMOS transistor region NR or the PMOS transistor region PR in FIG. 1. The semiconductor region may include regions separated from each other by a device isolation layer 111. The device isolation 111 may extend in a first direction (hereinafter, referred to as ‘an x-direction’), and the regions of the semiconductor region may be separated from each other in a second direction (hereinafter, referred to as ‘a y-direction’). The separated regions of the semiconductor region may correspond to the first and second NMOS regions N1 and N2, or the first and second PMOS regions P1 and P2 in FIG. 1. A plurality of transistors TR may be disposed at both sides of the device isolation layer 111. The plurality of transistors TR may have occupied areas that are different from each other, as illustrated in FIG. 2. The occupied areas of the transistors TR may be determined depending on arrangement, uses, and/or structures of the transistors TR.

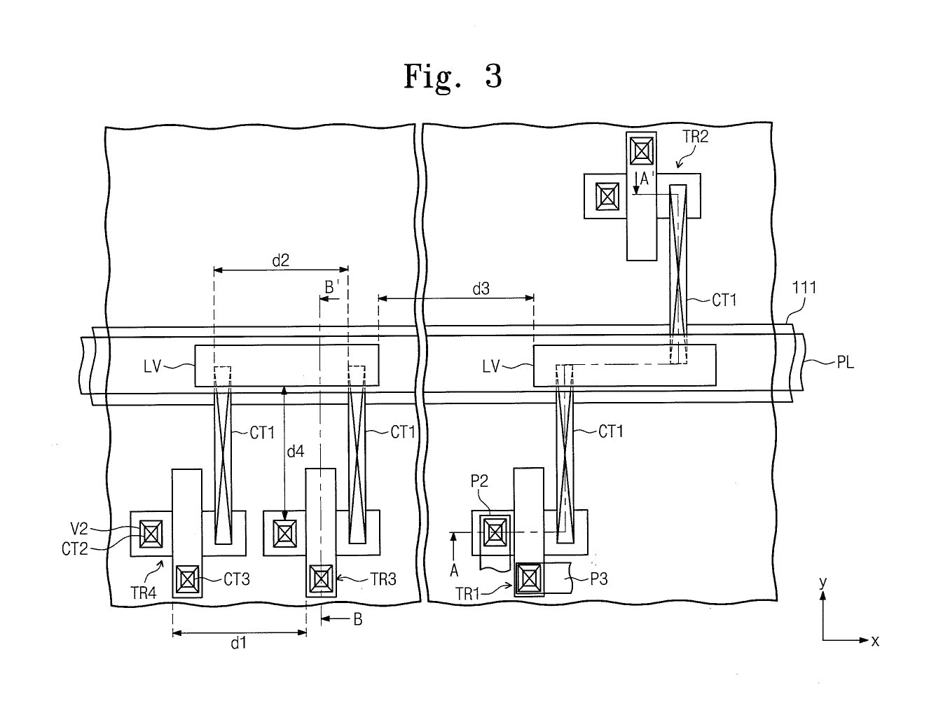

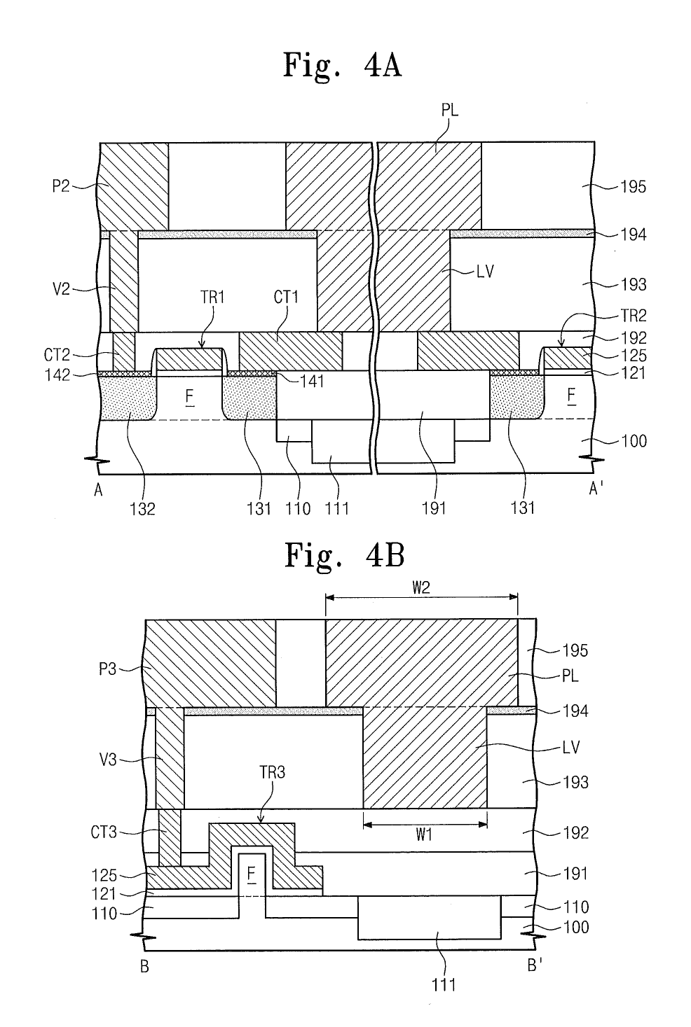

A first conductive line PL (hereinafter, referred to as ‘a common conductive line PL’) may be disposed along the x-direction corresponding to the extending direction of the device isolation layer 111. The transistors TR may be electrically connected in common to the common conductive line PL through first contacts CT1 and first vias (hereinafter, referred to as ‘long vias LV’). A connection structure of the transistors TR and the common conductive line PL will be described in more detail with reference to FIGS. 3, 4A, and 4B.

FIG. 3 is an enlarged view of FIG. 2. FIG. 4A is a cross-sectional view taken along a line A-A′ of FIG. 3, and FIG. 4B is a cross-sectional view taken along a line B-B′ of FIG. 3.

Referring to FIGS. 3, 4A, and 4B, a plurality of transistors TR1, TR2, TR3, and TR4 may be provided on a substrate 100. For example, the substrate 100 may be a silicon substrate, a germanium substrate, or a silicon-on-insulator (SOI) substrate. The device isolation layer 111 (hereinafter, referred to as ‘a first device isolation layer) extending in the x-direction may be disposed between the transistors TR1 to TR4. The first device isolation layer 111 may reduce leakage current from the common conductive line as described below.

The transistors TR1 to TR4 may be the same type of transistors. For example, all of the transistors TR1 may be NMOS transistors, or PMOS transistors. The transistors TR1 to TR4 may be fin field effect transistors including fin portions F protruding from the substrate 100. The fin portion F may protrude from a top surface of the substrate 100 exposed by a second device isolation layer 110. The first device isolation layer 111 may be thicker than the second device isolation layer 110. A boundary between the first and second device isolation layers 111 and 110 is illustrated in FIGS. 4A and 4B for distinction between the first and second device isolation layers 111 and 110. However, the boundary may not exist between the first and second device isolation layers 111 and 110. A first interlayer insulating layer 191 may be provided to cover the first and second device isolation layers 111 and 110. The first and second device isolation layers 111 and 110 and the first interlayer insulating layer 191 may include silicon oxide and/or silicon oxynitride.

Each of the transistors TR1 to TR4 may include a gate dielectric layer 121 and a gate electrode 125 sequentially stacked on the fin portion F. The gate dielectric layer 121 and the gate electrode 125 may extend in a direction crossing an extending direction (e.g., the x-direction) of the fin portion F. In some embodiments, portions of the gate dielectric layer 121 and the gate electrode 125 may extend in the x-direction, and the remaining portions of the gate dielectric layer 121 and the gate electrode 125 may extend in the y-direction. The gate dielectric layer 121 may include a silicon oxide layer, a silicon oxynitride layer, and/or a high-k dielectric layer. The high-k dielectric layer has a dielectric constant higher than that of the silicon oxide layer. The gate electrode 125 may include at least one of a polysilicon, a doped semiconductor, a metal, or a conductive metal nitride.

Each of the transistors TR1 to TR4 may include a first dopant region 131 and a second dopant region 132. If the transistors TR1 to TR4 are the NMOS transistors, the first dopant regions 131 may be source regions and the second dopant regions 132 may be drain regions. If the transistors TR1 to TR4 are the PMOS transistors, the first dopant regions 131 may be drain regions and the second dopant regions 132 may be source regions. If the transistors TR1 to TR4 are the NMOS transistors, the first and second dopant regions 131 and 132 may be regions doped with n-type dopants. If the transistors TR1 to TR4 are the PMOS transistors, the first and second dopant regions 131 and 132 may be regions doped with p-type dopants.

First contacts CT1 may be provided on the first dopant regions 131. The first contacts CT1 may extend from the first dopant regions 131 onto the first device isolation layer 111. In other words, the first contacts CT1 may extend in a direction (e.g., the y-direction) crossing the extending direction (e.g., the x-direction) of the first device isolation layer 111. The first contacts CT1 may penetrate a second interlayer insulating layer 192 covering the transistors TR1 to TR4 and may be connected to the first dopant regions 131.

A metal-silicide layer 141 may be provided between the first contact CT1 and the first dopant region 131. For example, the metal-silicide layer 141 may include tungsten silicide, titanium silicide, or tantalum silicide. The first contacts CT1 may include at least one of a doped semiconductor, a metal, and/or a conductive metal nitride. For example, the first contacts CT1 may include at least one of copper, aluminum, gold, silver, tungsten, or titanium.

At least one first via (hereinafter, referred to as ‘a long via LV’) may be disposed on the first contacts CT1 and may be connected in common to a plurality of first contacts CT1 adjacent to each other of the first contacts CT 1. As illustrated in FIG. 3, the long via LV may include a plurality of long vias LV, and the long vias LV may be spaced apart from each other in the x-direction.

A common conductive line PL may be disposed on the long vias LV and may extend along the first device isolation layer 111. The first dopant regions 131 of the transistors TR1 to TR4 are electrically connected to the common conductive line PL through the first contacts CT1 and the long vias LV. If the transistors TR1 to TR4 are the NMOS transistors, the common conductive line PL may be a path supplied with a source voltage Vss, for example, a ground voltage). If the transistors TR1 to TR4 are the PMOS transistors, the common conductive line PL may be a path supplied with a drain voltage Vdd, for example, a power voltage. The long vias LV may be provided in a third interlayer insulating layer 193, and the common conductive line PL may be provided in a fourth interlayer insulating layer 195. An etch stop layer 194 may be disposed between the third interlayer insulating layer 193 and the fourth interlayer insulating layer 195. The etch stop layer 194 may include a material having an etch selectivity with respect to the third and fourth interlayer insulating layers 193 and 195. For example, if the third and fourth interlayer insulating layers 193 and 195 include silicon oxide, the etch stop layer 194 may include silicon nitride.

Each of the long vias LV is illustrated to be connected to two transistors in FIG. 3. However, the inventive concept is not limited thereto. Each of the long vias LV may be connected to three or more transistors, as illustrated in FIG. 2. Each of the long vias LV may be connected in common to the plurality of first contacts CT1. Since the semiconductor device includes the long vias LV, it is possible to overcome limitations of a photolithography technique caused in a case that the first contacts CT1 are connected to the common conductive line PL through individual vias. In other words, if individual vias are formed to be connected to the first contacts CT1, respectively, a distance between the individual vias may be limited to a specific distance or more due to the limitations of the lithography technique. A plurality of patterning processes using a plurality of masks may be performed in order to overcome the limit of the minimum distance. In this case, processes for the formation of the individual vias may be complicated to increase manufacture costs of the semiconductor device. According to some embodiments of the inventive concept, individual vias within a predetermined distance may be unified to overcome the above problems. The predetermined distance will be described in more detail hereinafter.

The predetermined distance may be determined depending on a minimum pitch between the gate electrodes 125 of the transistors TR1 to TR4 in the x-direction, for example, a contacted poly pitch (CPP). For example, some embodiments provide that the minimum pitch may be about 100 nm. However, the inventive concept is not limited thereto.

In some embodiments, if a distance between the third and fourth transistors TR3 and TR4 is the minimum pitch d1 and the predetermined distance is less than the minimum pitch d1, the first contacts CT1 may be connected to the common conductive line PL through the long vias LV instead of the individual vias.

Even though the predetermined distance is greater than the minimum pitch d1 and less than twice the minimum pitch d1, the first contacts CT1 may also be connected to the common conductive line PL through the long vias LV instead of the individual vias.

If two transistors are spaced apart from each other by a pitch equal to or greater than twice the minimum pitch d1, the first contacts of the two transistors may be connected to the long vias LV spaced apart from each other, respectively. In some embodiments, a distance d3 between the long vias LV may be equal to or greater than twice the minimum pitch d1. For example, the distance d3 between the long vias LV may be about 200 nm or more. In other words, if a pitch between the third and first transistors TR3 and TR1 is equal to or greater than twice the minimum pitch d1, the first contacts CT1 of the third and first transistors TR3 and TR1 may be connected to the long vias LV spaced apart from each other, respectively. The distance d3 between the long vias LV may be greater than a distance d2 between the first contacts CT1 connected to one of the long vias LV.

A thickness of each of the long vias LV may be about 2 times to about 4 times greater than a thickness of each of the first contacts CT1 in a direction vertical to the substrate 100. The thickness of the long via LV may be less than a thickness of the common conductive line PL. A width of the long via LV in the y-direction may be less than a width of the common conductive line PL in the y-direction. In some embodiments, the width of the long via LV may be within a range of about 60% to about 90% of the width of the common conductive line PL. For example, the width of the common conductive line PL may have a range of about 32 nm to about 120 nm. Top surfaces of the long vias LV may be completely covered by the common conductive line PL.

In some embodiments, the long vias LV may include the same material as the common conductive line PL, and an interface may not exist between the common conductive line PL and the long vias LV. The long vias LV and the common conductive line PL may include at least one of a doped semiconductor, a polysilicon, a metal, or a conductive metal nitride. For example, the long vias LV and the common conductive line PL may include at least one of copper, aluminum, gold, silver, tungsten, and/or titanium.

Second contacts CT2 may be disposed on the second dopant regions 132. The second contacts CT2 may include the same material as the first contacts CT1. A metal-silicide layer may be disposed between the second contact CT2 and the second dopant region 132. For example, the metal-silicide layer 142 may include tungsten silicide, titanium silicide, and/or tantalum silicide.

The second dopant regions 132 may be electrically connected to second conductive lines P2 through the second contacts CT2 and second vias V2 disposed on the second contacts CT2. Third contacts CT3 may be disposed on the gate electrodes 125. The third contacts CT3 may include the same material as the first contacts CT1. The gate electrodes 125 may be electrically connected to third conductive lines P3 through the third contacts CT3 and third vias V3 disposed on the third contacts CT3. A top surface of each of the second and third contacts CT2 and CT3 may have a first width in the x-direction and a second width in the y-direction. The top surface of each of the second and third contacts CT2 and CT3 may have the first width and the second width substantially equal to each other unlike the first contacts CT1. A top surface of each of the second and third vias V2 and V3 may have a first width in the x-direction and a second width in the y-direction. The first and second widths of the top surface of each of the second and third vias V2 and V3 may be substantially equal to each other unlike the long vias LV.

The second and third vias V2 and V3 may include the same material as the long vias LV. The second and third vias V2 and V3 may be disposed at substantially the same level as the long vias LV from the top surface of the substrate 100. The second and third conductive lines P2 and P3 may include the same material as the common conductive line PL. The second and third conductive lines P2 and P3 may be disposed at substantially the same level as the common conductive line PL from the top surface of the substrate 100. As illustrated in FIGS. 3, 4A, and 4B, the second vias V2 may be disposed on the second contacts CT2, respectively, and the third vias V3 may be disposed on the third contacts CT3, respectively. Additionally, the second and third vias V2 and V3 may be spaced apart from each other. However, the inventive concept is not limited thereto. In some embodiments, one second via V2 may electrically connect a plurality of second contacts CT2 to the second conductive line P2.

A minimum distance (e.g., a distance d4) of distances between the long vias LV and the second and third vias V2 and V3 may be a minimum pitch in the y-direction. The minimum pitch in the y-direction may be varied according to shapes of the long vias LV and shapes of the second and third vias V2 and V3. The minimum pitch in the y-direction may be equal to or different from the minimum pitch in the x-direction. In some embodiments of the inventive concept, the width W1 of the long via LV may be less than the width W2 of the common conductive line PL. Thus, it may be possible to obtain the minimum distance between the long vias LV and the second and third vias V2 and V3.

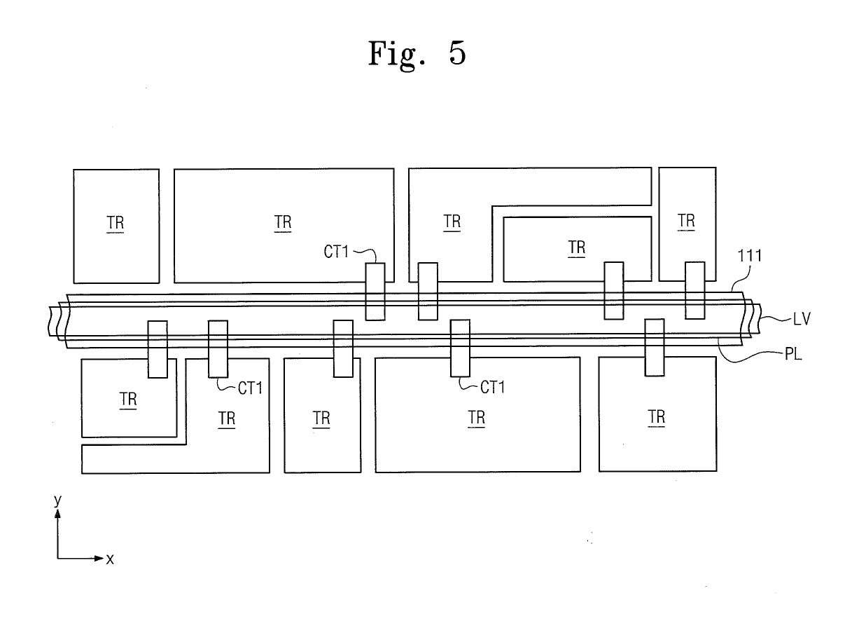

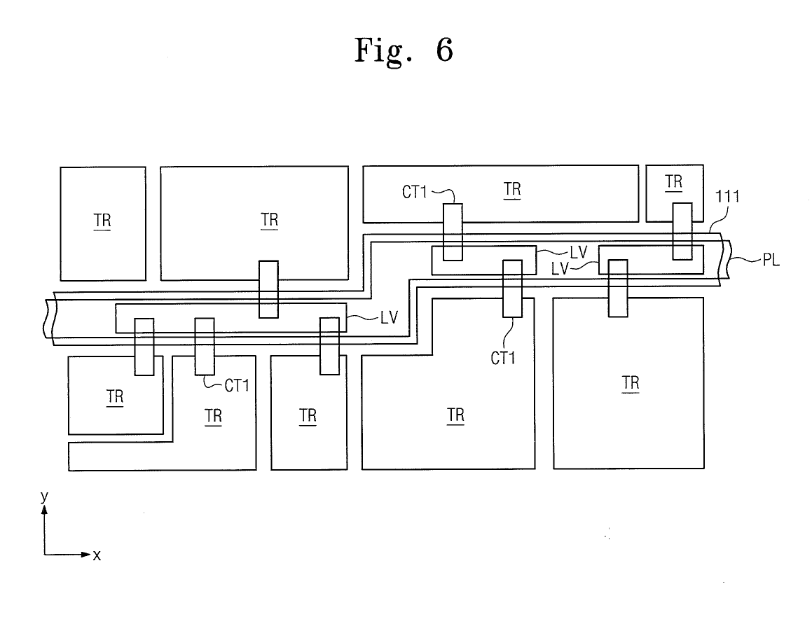

FIGS. 5 and 6 are plan views illustrating transistor regions according to some embodiments of the inventive concept. In the following embodiments, the descriptions to the same elements as described in the aforementioned embodiments will be omitted or mentioned briefly for the purpose of ease and convenience in explanation.

In FIG. 5, one long via LV extends along the extending direction of the common conductive line PL and the extending direction of the first device isolation layer 111, and the first contacts connected to transistors TR are connected to the one long via LV. The common conductive line PL and the first device isolation layer 111 have linear shapes extending in the x-direction in FIGS. 1 to 3, 4A, 4B, and 5. However, the inventive concept is not limited thereto. In another embodiment, the common conductive line PL and the first device isolation layer 111 may include portions extending along the y-direction in a region, as illustrated in FIG. 6.

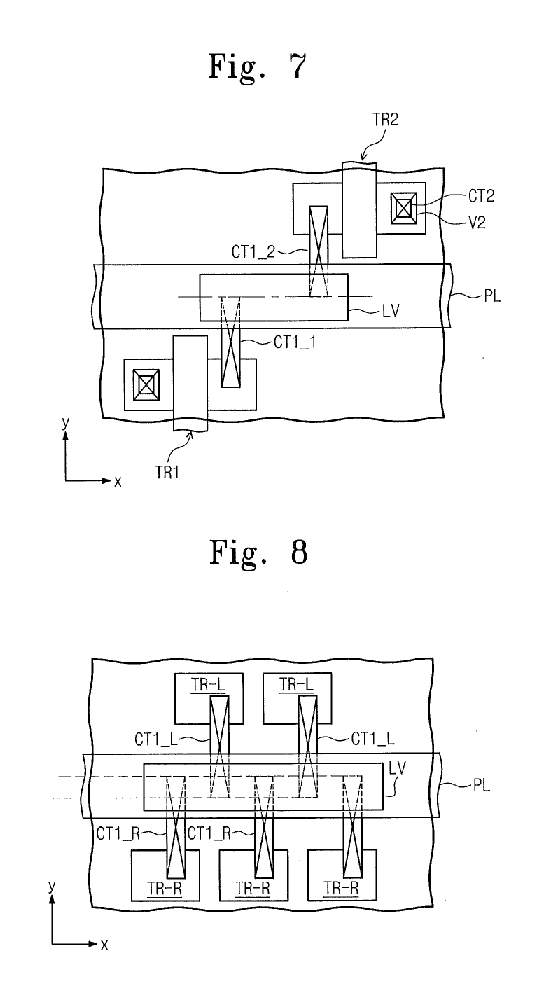

FIGS. 7 to 10 are plan views illustrating arrangement and shapes of first contacts CT1 in more detail.

Referring to FIG. 7, a long via LV may be disposed between first and second transistors TR1 and TR2. Ends of first contacts CT1_1 and CT1_2 of the first and second transistors TR1 and TR2 may be aligned with a major axis of the long via LV. Referring to FIG. 8, ends of first contacts CT1_L extending from transistors TR-L disposed at a side of a long via LV may alternate with ends of first contacts CT1_R extending from transistors TR-R disposed at another side of the long via LV. In the y-direction, a portion of the ends of the first contacts CT1_L of the transistor TR-L may be different from that of the ends of the first contacts CT1_R of the transistors TR-R.

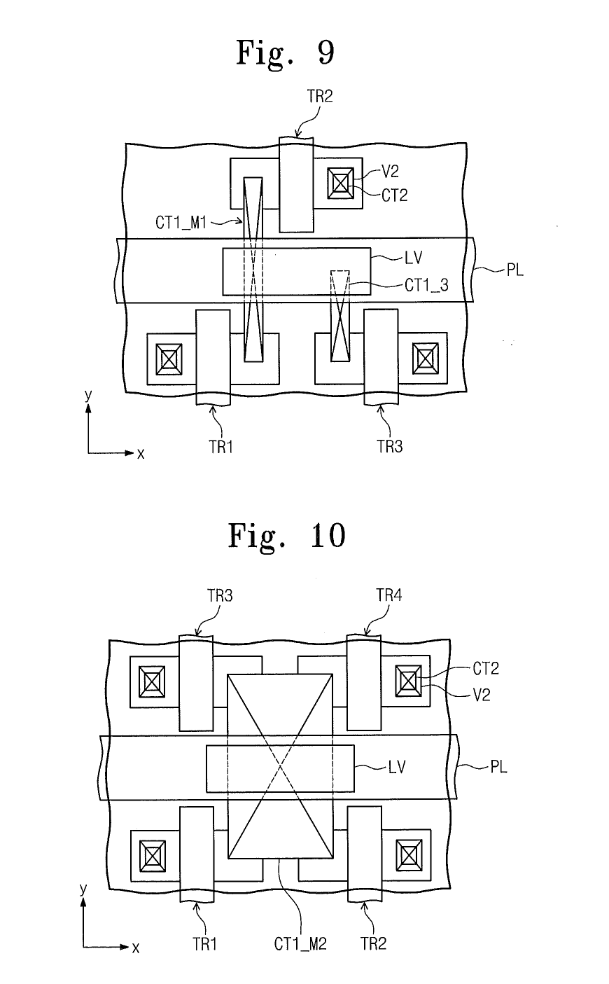

Referring to FIG. 9, a first transistor TR1 and a second transistor TR2 that are respectively disposed at both sides of a long via LV may share a first merged contact CT1_M1. In other words, a first contact of the first transistor TR1 may be physically connected to a first contact of the second transistor TR2 without an interface therebetween. On the contrary, a first contact CT1_3 of a third transistor TR3 may be separated from the first merged contact CT1_M1. Referring to FIG. 10, first to fourth transistors TR1 to TR4 that are disposed at both sides of a long via LV may share a first merged contact CT1_M2. If a pitch between the first contacts is less than the minimum pitch, the merged contact illustrated in FIG. 9 or 10 may electrically connect a plurality of transistors to one long via LV without a plurality of patterning processes using a plurality of masks.

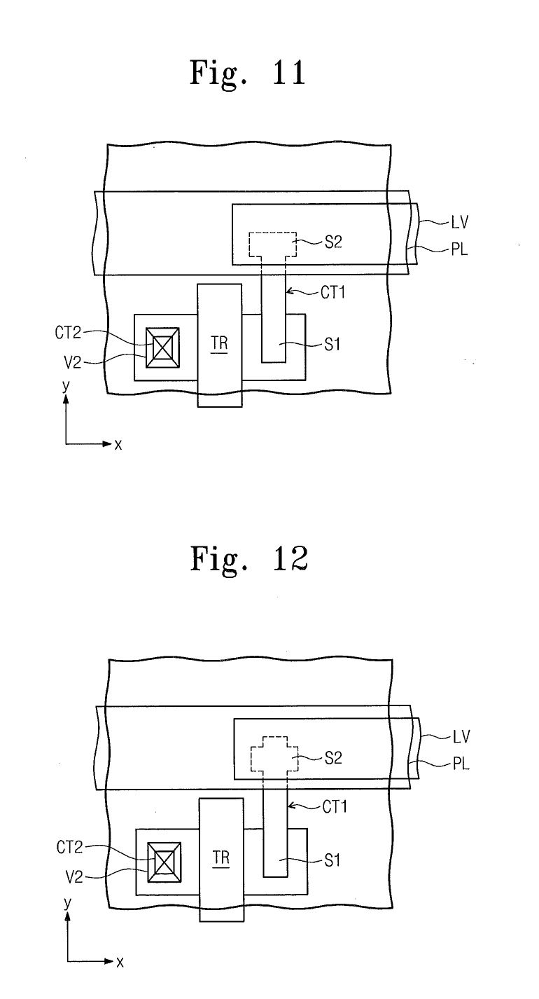

FIGS. 11 and 12 are plan views illustrating other examples of a structure of a first contact according to example embodiments of the inventive concept. Referring to FIG. 11, a first contact CT1 may include a first portion S1 adjacent a transistor TR and a second portion S2 extending from the first portion S1 under a long via LV. In some embodiments, the first contact CT1 may be T-shaped when viewed from a plan view. In other words, a width of the second portion S2 in the x-direction may be greater than a width of the first portion S1 in the x-direction. A sufficient signal pass may be formed between the first contact CT1 and the long via LV due to the second portion S2 having the relatively great width. For example, the width of the second portion S2 may be within a range of about 30 nm to about 40 nm. For example, a width of the first contact CT1 in the y-direction may be about 100 nm or less.

FIG. 12 illustrates a first contact CT1 which further includes a portion protruding from the second portion S2 in the y-direction. According to some embodiments of the inventive concept, the shape of the first contact CT1 is not limited to the shapes illustrated in FIGS. 11 and 12. The first contact CT1 may be variously modified to have a portion that overlaps with the long via LV and has the relatively great width.

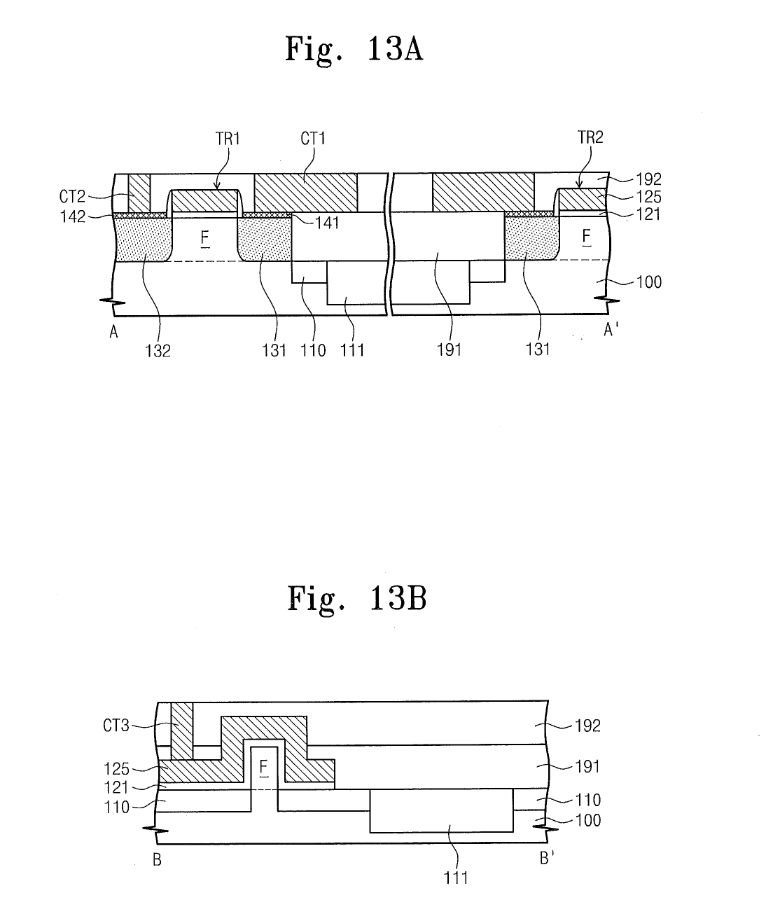

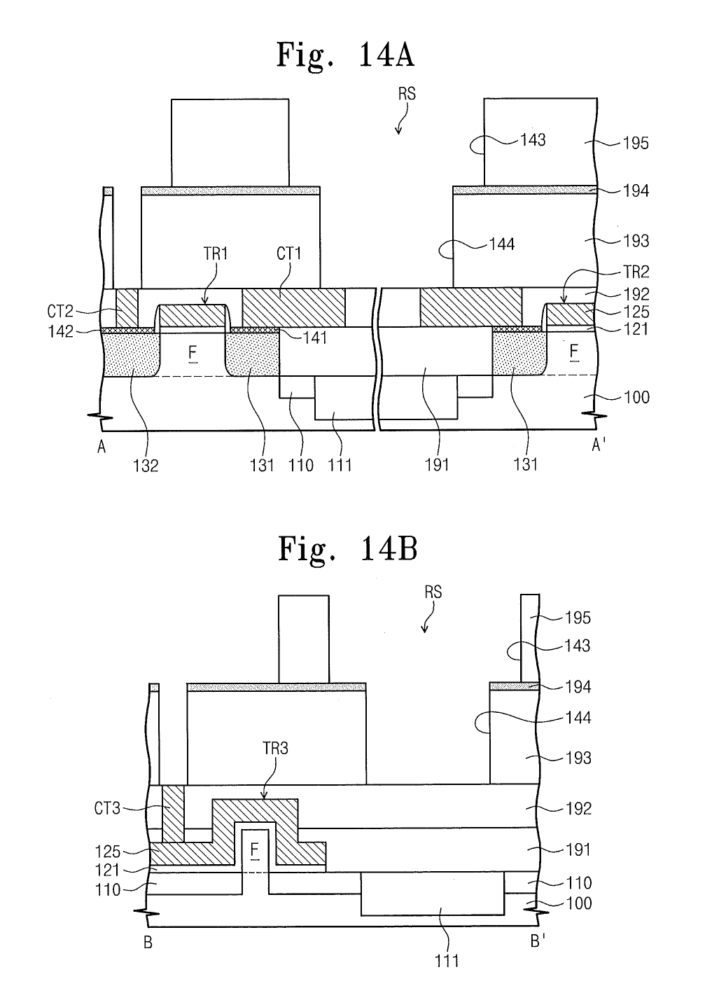

FIGS. 13A, 13B, 14A, and 14B are cross-sectional views illustrating methods of fabricating a semiconductor device according to some embodiments of the inventive concept. FIGS. 13A and 14A are cross-sectional views taken along a line A-A′ of FIG. 3, and FIGS. 13B and 14B are cross-sectional views taken along a line B-B′ of FIG. 3.

Referring to FIGS. 13A and 13B, fin portions F protruding from a substrate 100 may be formed. Device isolation layers 111 and 110 may be formed in the substrate 100 and then upper portions of the device isolation layers 111 and 110 may be removed to form the fin portions F. Alternatively, an epitaxial growth process may be performed on a top surface of the substrate 100 exposed by the device isolation layers 111 and 110, thereby forming the fin portions F. The device isolation layers 111 and 110 may include a first device isolation layer 111 and a second device isolation layer 110. The first device isolation layer 111 may be thicker than the second device isolation layer 110. Forming the device isolation layers 111 and 110 may include a plurality of etching processes and a plurality of deposition processes.

An insulating layer and a conductive layer may be sequentially formed on the fin portions F, and then a patterning process may be performed on the conductive layer and the insulating layer, thereby forming a gate dielectric layer 121 and a gate electrode 125. The gate dielectric layer 121 may include at least one of a silicon oxide layer, a silicon oxynitride layer, or a high-k dielectric layer. The high-k dielectric layer has a dielectric constant greater than that of the silicon oxide layer. The gate electrode 125 may include at least one of a doped semiconductor, a metal, or a conductive metal nitride. First and second dopant regions 131 and 132 may be formed at both sides of the gate electrode 125, respectively. The first and second dopant regions 131 and 132 may be formed by an ion implantation process. Metal-silicide layers 141 and 142 may be formed on the first and second dopant regions 131 and 132, respectively. A metal layer may be formed on the dopant regions 131 and 132 and then a thermal treatment process may be performed on the metal layer to form the metal-silicide layers 141 and 142. In some embodiments, the formation process of the metal-silicide layers 141 and 142 may be omitted.

After a first interlayer insulating layer 191 is formed between the fin portions F, a second interlayer insulating layer 192 may be formed to cover the fin portions F. In some embodiments, the first and second interlayer insulating layers 191 and 192 may be formed by chemical vapor deposition (CVD) processes, respectively. The first and second interlayer insulating layers 191 and 192 may include silicon oxide layers, respectively. An etch stop layer may be provided between the first and second interlayer insulating layers 191 and 192. The etch stop layer may have an etch selectivity with respect to the first and second interlayer insulating layers 191 and 192. For example, the etch stop layer may include a silicon nitride layer.

First, second, and third contacts CT1, CT2, and CT3 may be formed to penetrate the second interlayer insulating layer 192 and/or the first interlayer insulating layer 191. The first contact CT1 may be formed on the first dopant region 131, and the second contact CT2 may be formed on the second dopant region 132. The third contact CT3 may be formed on the gate electrode 125. Contact-holes may be formed to penetrate the second interlayer insulating layer 192 and/or the first interlayer insulating layer 191, and then a doped semiconductor, a metal, or a metal nitride may be deposited in the contact-holes, thereby forming the first to third contacts CT1, CT2, and CT3. In some embodiments, the deposition process may be a CVD process or a sputtering process. The first contact CT1 may be formed to extend from the first dopant region 131 onto the first device isolation layer 111.

Referring to FIGS. 14A and 14B, a third interlayer insulating layer 193, an etch stop layer 194, and a fourth interlayer insulating layer 195 may be sequentially formed on the resultant structure having the contacts CT1, CT2, and CT3. The etch stop layer 194 may include a material having an etch selectivity with respect to the third and fourth interlayer insulating layers 193 and 195. In some embodiments, if the third and fourth interlayer insulating layers 193 and 195 are silicon oxide layers, the etch stop layer 194 may be a silicon nitride layer.

A recess region RS may be formed to include a via-hole 144 penetrating the third interlayer insulating layer 193 and a trench 143 penetrating the fourth interlayer insulating layer 195. A plurality of the recess regions RS may be formed on the substrate 100. In some embodiments, the formation process of the via-hole 144 and the trench 143 may be a part of a dual damascene process. In an embodiment (e.g., a trench-first method), the fourth interlayer insulating layer 195 may be etched until the etch stop layer 194 is exposed, and then the via-hole 141 may be formed to penetrate the etch stop layer 194 and the third interlayer insulating layer 193. In some embodiments (e.g., a via-first method), the via-hole 144 may be formed to successively penetrate the fourth interlayer insulating layer 195, the etch stop layer 194, and the third interlayer insulating layer 193, and then the fourth interlayer insulating layer 195 may be etched to form the trench 143 exposing the etch stop layer 194. In some embodiments, the via-hole 144 and the trench 143 may be formed by a self-aligned dual damascene process.

Referring again to FIGS. 4A and 4B, a conductive material may be formed in the via-holes 144 and the trenches 143. As a result, the vias LV, L2, and L3 may be formed in the via-holes 144, respectively, and the conductive lines PL, P2, and P3 may be formed in the trenches 143, respectively. In other words, the vias LV, L2, and L3 and the conductive lines PL, P2, and P3 may be formed of the same conductive material at the same time.

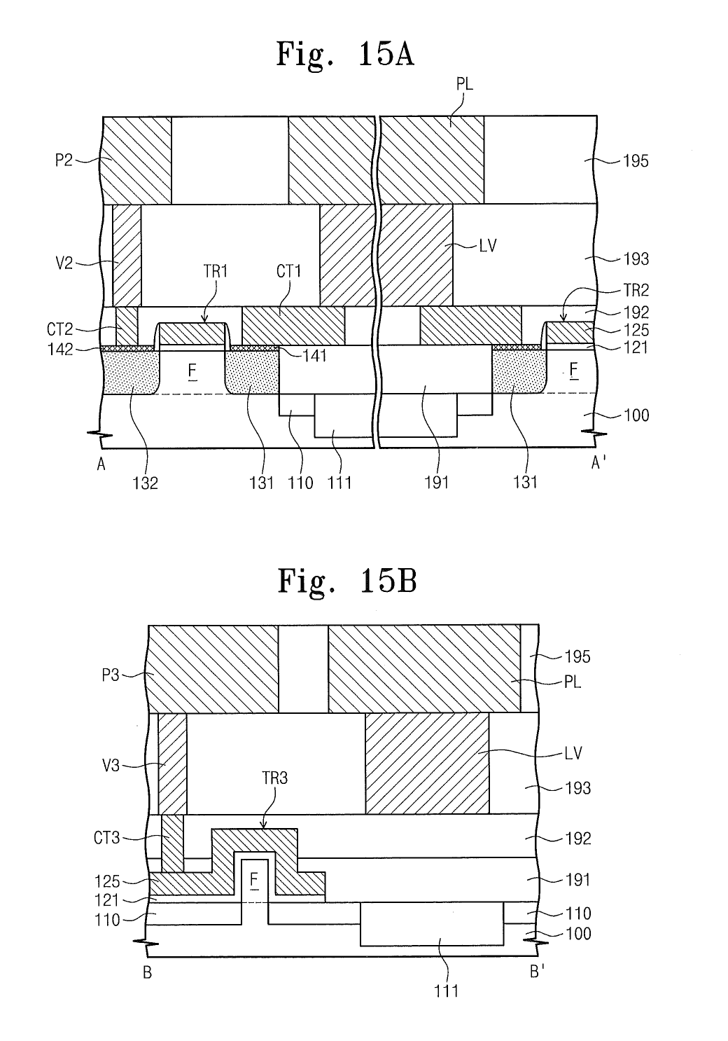

FIGS. 15A and 15B are cross-sectional views illustrating methods of fabricating a semiconductor device according to other embodiments of the inventive concept. In the present embodiment, the descriptions to the same elements as described in the aforementioned embodiments will be omitted or mentioned briefly for the purpose of ease and convenience in explanation.

In some embodiments, the vias LV, L2, L3 may be formed independently of the conductive lines PL, P2, and P3. In some embodiments, after the vias LV, L2, and L3 are formed to penetrate the third interlayer insulating layer 193, the fourth interlayer insulating layer 195 may be formed on the vias LV, L2, and L3. Thereafter, the conductive lines PL, P2, and P3 may be formed to penetrate the fourth interlayer insulating layer 195. A bottom surface of the common conductive line PL may be formed to be in contact with a top surface of the long via LV. The vias LV, L2, and L3 may be formed of the same material as the conductive lines PL, P2, and P3. In some embodiments, the vias LV, L2, and L3 may be formed of a different material from the conductive lines PL, P2, and P3.

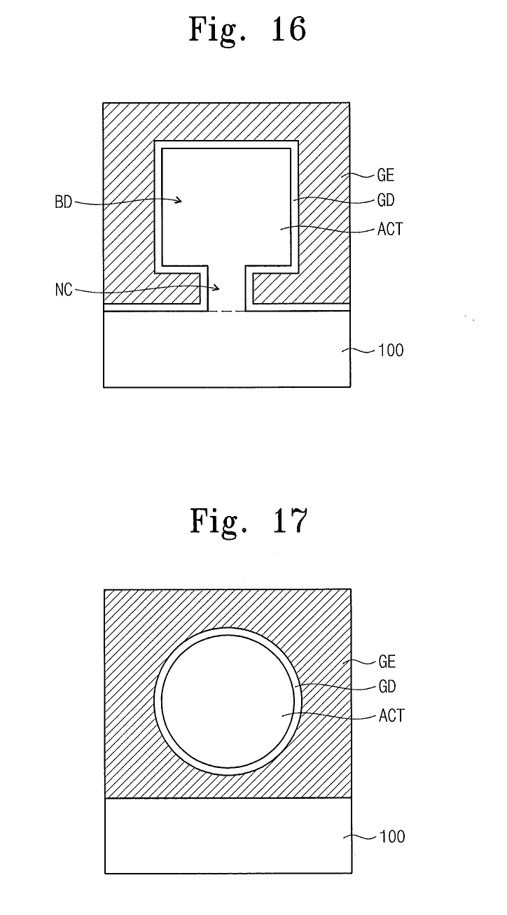

As described above, an active region of the transistor may include the fin shape. However, the inventive concept is not limited thereto. The shape of the active region may be variously modified. FIG. 16 illustrates another example of an active region of a semiconductor device according to some embodiments of the inventive concept. In the present embodiment, a cross section of an active region ACT of the transistor may have an omega-shape including a neck portion NC adjacent a substrate 100 and a body portion BD having a wider width than the neck portion NC. A gate dielectric layer GD and a gate electrode GE may be sequentially disposed on the active region ACT. A portion of the gate electrode GE may extend under the active region ACT (i.e., the body portion BD).

FIG. 17 illustrates still another example of an active region of a semiconductor device according to some embodiments of the inventive concept. In the present embodiment, the transistor may include an active region ACT having a nanowire-shape spaced apart from a substrate 100. A gate dielectric layer GD and a gate electrode GE may be sequentially provided on the active region ACT. The gate electrode GE may extend between the active region ACT and the substrate 100.

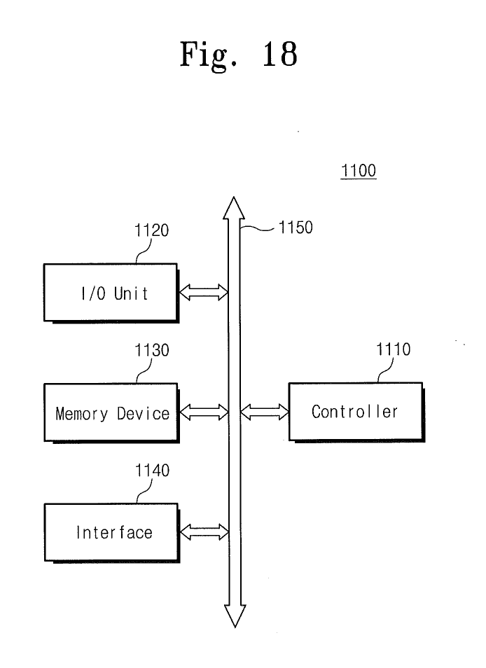

FIG. 18 is a schematic block diagram illustrating an example of electronic systems including semiconductor devices according to some embodiments of the inventive concept.

Referring to FIG. 18, an electronic system 1100 according to some embodiments of the inventive concept may include a controller 1110, an input/output (I/O) unit 1120, a memory device 1130, an interface unit 1140, and a data bus 1150. At least two of the controller 1110, the I/O unit 1120, the memory device 1130 and the interface unit 1140 may communicate with each other through the data bus 1150. The data bus 1150 may correspond to a path through which electrical signals are transmitted.

The controller 1110 may include at least one of a microprocessor, a digital signal processor, a microcontroller or another logic device. The other logic device may have a similar function to any one of the microprocessor, the digital signal processor and the microcontroller. The I/O unit 1120 may include a keypad, a keyboard and/or a display unit, among others. The memory device 1130 may store data and/or commands. The interface unit 1140 may transmit electrical data to a communication network or may receive electrical data from a communication network. The interface unit 1140 may operate by wireless or cable. For example, the interface unit 1140 may include an antenna for wireless communication or a transceiver for cable communication. Although not shown in the drawings, the electronic system 1100 may further include a fast DRAM device and/or a fast SRAM device, which acts as a cache memory for improving an operation of the controller 1110. The semiconductor devices according to embodiments of the inventive concept may be provided into the memory device 1130, the controller 1110, and/or the I/O unit 1120.

The electronic system 1100 may be applied to a personal digital assistant (PDA), a portable computer, a web tablet, a wireless phone, a mobile phone, a digital music player, a memory card or other electronic products. The other electronic products may receive or transmit information data by wireless.

According to some embodiments of the inventive concept, the long via connecting a plurality of the contacts to the conductive line may be provided without employment of a plurality of masks.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A semiconductor device comprising:
a plurality of transistors on a substrate, the plurality of transistors including first dopant regions;
first contacts extending from the first dopant regions in a first direction;
a long via on the first contacts, the long via connected in common to a plurality of first contacts that are adjacent one another; and
a common conductive line on the long via and extending in a second direction crossing the first direction, the common conductive line electrically connecting the first dopant regions to each other through the long via and the plurality of first contacts.

2. The semiconductor device of claim 1, further comprising a device isolation layer in the substrate,
wherein the common conductive line vertically overlaps with the device isolation layer, and
wherein the common conductive line extends along the device isolation layer.

3. The semiconductor device of claim 2, wherein the device isolation layer comprises:
a first device isolation layer under the common conductive line and extending along the common conductive line; and
a second device isolation layer defining an active region of the substrate,
wherein the first device isolation layer is thicker in a vertical direction relative to the substrate than the second device isolation layer.

4. The semiconductor device of claim 3, wherein the plurality of transistors are disposed at both sides of the first device isolation layer; and
wherein the first contacts extend onto the first device isolation layer.

5. The semiconductor device of claim 3, wherein ends of the first contacts of the transistors disposed at a side of the first device isolation layer are aligned with each other in an extending direction of the common conductive line.

6. The semiconductor device of claim 1, wherein the long via includes a same material as the common conductive line; and
wherein an interface does not exist between the long via and the common conductive line.

7. The semiconductor device of claim 1, wherein a top surface of the long via is in contact with a bottom surface of the common conductive line.

8. The semiconductor device of claim 1, wherein a top surface of the long via is completely covered by the common conductive line.

9. The semiconductor device of claim 1, wherein a width of the long via in the first direction is less than a width of the common conductive line in the first direction.

10. The semiconductor device of claim 9, wherein the width of the long via in the first direction is less than a width of the long via in the second direction.

11. The semiconductor device of claim 1, wherein a thickness of the long via is about 2 times to about 4 times greater than a thickness of the first contact.

12. The semiconductor device of claim 1, wherein the long via includes a plurality of long vias; and
wherein the plurality of long vias are spaced apart from each other in the second direction.

13. The semiconductor device of claim 12, wherein a distance between the plurality of long vias is equal to or greater than twice a minimum pitch between gates of the plurality of transistors.

14. The semiconductor device of claim 12, wherein a distance between the plurality of long vias is greater than a distance between the first contacts connected to one of the long vias.

15. The semiconductor device of claim 1, wherein some of the first contacts connected to one of the long vias are physically connected to each other.

16. The semiconductor device of claim 1, wherein at least one of the first contacts comprises:
a first portion; and
a second portion extending from the first portion and extending under the long via,
wherein a width of the second portion is greater than a width of the first portion.

17. The semiconductor device of claim 1, wherein the plurality of transistors further comprise second dopant regions,
wherein the semiconductor device further comprises:
second contacts on the second dopant regions; and
third contacts on gate electrodes of the plurality of transistors.

18. The semiconductor device of claim 17, further comprising:
second vias on the second contacts; and
third vias on the third contacts,
wherein the second vias and the third vias are at a substantially same level as the long via from a top surface of the substrate.

19. The semiconductor device of claim 18, wherein a distance between the long via and the second via or third via is equal to or greater than a minimum pitch between the gate electrodes.

20. The semiconductor device of claim 18, further comprising:
a second conductive line on the second via; and
a third conductive line on the third via,
wherein the second and third conductive lines are at a substantially same level as the common conductive line from the top surface of the substrate.

21. The semiconductor device of claim 1, wherein the plurality of transistors comprise the same conductive type transistors.

22. The semiconductor device of claim 1, wherein the plurality of transistors are NMOS transistors; and
wherein the first dopant regions are source regions of the plurality of transistors.

23. The semiconductor device of claim 1, wherein the plurality of transistors are PMOS transistors; and
wherein the first dopant regions are drain regions of the plurality of transistors.

24. A semiconductor device comprising:
a device isolation layer in a substrate and extending in one direction;
a plurality of transistors at both sides of the device isolation layer, the plurality of transistors including first dopant regions;
first contacts extending from the first dopant regions onto the device isolation layer;
a long via provided on the first contacts, the long via connected in common to a plurality of first contacts that are adjacent one another; and
a common conductive line connected to a top surface of the long via, the common conductive line extending along the device isolation layer.

25. The semiconductor device of claim 24, wherein the first contacts extend in a direction crossing an extending direction of the common conductive line.

26. The semiconductor device of claim 24, wherein the common conductive line is electrically connected to the first dopant regions.

27. The semiconductor device of claim 24, wherein the top surface of the long via is in contact with a bottom surface of the common conductive line; and
wherein the top surface of the long via is completely covered by the common conductive line.

28. The semiconductor device of claim 24, wherein a width of the long via is less than a width of the common conductive line in a direction crossing an extending direction of the common conductive line.

29. The semiconductor device of claim 24, wherein the long via includes a plurality of long vias, and
wherein the plurality of long vias are spaced apart from each other in an extending direction of the common conductive line.

30. The semiconductor device of claim 29, wherein a distance between the plurality of long vias is equal to or greater than twice a minimum pitch between gates of the plurality of transistors.

31. The semiconductor device of claim 29, wherein a distance between the plurality of long vias is greater than a distance between the first contacts connected to one of the long vias.

32. The semiconductor device of claim 24, wherein some of the first contacts connected to one of the long vias are physically connected to each other.

33. A semiconductor device comprising:
a plurality of transistors on a substrate and including first dopant regions;
contacts extending from the first dopant regions in one direction; and
a common conductive line on the contacts and extending in a direction crossing the one direction, the common conductive line electrically connected to the first dopant regions,
wherein the common conductive line includes a long via protruding from a bottom surface of the common conductive line toward the substrate; and
wherein the long via of the common conductive line is connected in common to a plurality of first contacts adjacent to each other of the first contacts.
